(19) United States
(12) Patent Application Publication
(10) Pub. No.: US 2021/0151529 A1
(43) Pub. Date: May 20, 2021

(54) OLED DISPLAY PANEL, MANUFACTURING METHOD THEREOF, AND OLED DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Ming XIE, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/753,885

(22) PCT Filed: Jan. 13, 2020
(86) PCT No.: PCT/CN2020/071674

§ 371 Date: Apr. 6, 2020

(30) Foreign Application Priority Data
Sep. 2, 2019 (CN) 201910822001.7

(51) Int. Cl. H01L 27/32; H01L 51/52; H01L 51/56

(52) U.S. Cl. CPC H01L 27/3246; H01L 51/0097; H01L 51/56; H01L 51/5253

(57) ABSTRACT

An organic light-emitting diode (OLED) display panel, a manufacturing method thereof, and an OLED display device are provided. The OLED display panel includes a substrate, a thin film transistor array layer, a planarization layer, a luminous layer, and a thin film encapsulation layer. The thin film encapsulation layer includes a first thin film encapsulation layer and a second thin film encapsulation layer. Through using the first thin film encapsulation layer to replace a pixel definition layer structure, side-encapsulation capability of the OLED display panel, resistance to water-oxygen, high thermal stability of products, and overall foldable performance are improved.

### CROSS REFERENCE TO RELATED APPLICATIONS

The present application claims priority of a Chinese patent application filed on Sep. 2, 2019 with the National Intellectual Property Administration, application number 201910822001.7, titled “OLED display panel, manufacturing method thereof, and OLED display device”, which is incorporated by reference in the present application in its entirety.

### FIELD OF INVENTION

The present invention relates to the field of display technologies, and in particular, to an organic light-emitting diode (OLED) display panel, a manufacturing method thereof, and an OLED display device.

### BACKGROUND OF INVENTION

Organic light-emitting diode (OLED) display devices have been widely used in the display field because of their advantages such as high brightness, full viewing angles, fast response times, and flexible display.

However, OLED display devices are very sensitive to the environment. Especially in a water-oxygen environment, moisture can enter pixel holes through holes above or on a side of an electrode, and penetrate from a cathode into an organic interface to cause organic material failure and ultimately form dark spots. In order to prevent moisture from entering the pixel holes, a thin film encapsulation (TFE) process is often used in the conventional art. The thin film encapsulation structure is generally composed of two inorganic layers and an organic layer positioned between the two inorganic layers. The organic and inorganic layers formed by a high temperature process have better adsorption capacity and lower moisture diffusion capacity. However, a current processing temperature for making the thin film encapsulation layer be at a better compatibility level with a bottom OLED light-emitting device is limited to conditions below 85° C., while encapsulation and protection are limited to merely from an upper surface of the device. It is impossible to fundamentally solve a phenomenon of high failure in an edge, in which moisture will enter the cathode/anode of a light-emitting device from a side edge, resulting in a reduction in service life of the light-emitting device or even failure.

In summary, it is necessary to provide a new OLED display panel, a manufacturing method thereof, and an OLED display device to solve the above technical problems.

### SUMMARY OF INVENTION

### Technical Problem

The invention provides an organic light-emitting diode (OLED) display panel, a method for manufacturing the same, and an OLED display device, which solves the problems that the conventional OLED display panels have poor lateral water-oxygen resistance of cathodes and anodes due to a low processing temperature in a thin film encapsulation forming process, and easily causing an edge failure in the light-emitting devices.

### Technical Solutions

To solve the above problems, the technical solution provided by the present invention is as follows.

An embodiment of the present invention provides an OLED display panel, including:

a base substrate;

a thin film transistor array layer disposed on the base substrate;

a planarization layer disposed on the thin film transistor array layer;

a luminous layer disposed on the planarization layer and positioned in a middle portion of the planarization layer; and

a thin film encapsulation layer including a first thin film encapsulation layer and a second thin film encapsulation layer, wherein the first thin film encapsulation layer is disposed on the planarization layer and positioned at an edge of the planarization layer, the first thin film encapsulation layer covers a side surface of the luminous layer, and the second thin film encapsulation layer is disposed on the luminous layer and the first thin film encapsulation layer.

According to the OLED display provided by the embodiment of the present invention, the first thin film encapsulation layer includes a first inorganic layer, an organic layer, and a second inorganic layer sequentially stacked on the planarization layer.

According to the OLED display provided by the embodiment of the present invention, a material of each of the first inorganic layer and the second inorganic layer includes one or more combinations of silicon nitride and silicon oxynitride, and a material of the organic layer is polymethyl methacrylate.

According to the OLED display provided by the embodiment of the present invention, a thickness of the first inorganic layer is 0.2 um, a material of the second inorganic layer is 0.2 um, and a thickness of the organic layer is 1.1 um.

According to the OLED display provided by the embodiment of the present invention, the OLED display panel further including a polarizer layer and a cover film, wherein the polarizer layer is disposed on the second thin film encapsulation layer, and the cover film is disposed on the polarizer layer.

According to the OLED display provided by the embodiment of the present invention, a material of the cover film is a glass.

According to the OLED display provided by the embodiment of the present invention, a material of the thin film transistor array layer is a low temperature polysilicon.

According to the OLED display provided by the embodiment of the present invention, the base substrate is a flexible substrate.

An embodiment of the present invention provides an OLED display device, including the above-mentioned OLED display panel, the OLED display panel including:

a base substrate;

a thin film transistor array layer disposed on the base substrate;

a planarization layer disposed on the thin film transistor array layer;

a luminous layer disposed on the planarization layer and positioned in a middle portion of the planarization layer; and

a thin film encapsulation layer including a first thin film encapsulation layer and a second thin film encapsulation layer, wherein the first thin film encapsulation layer is disposed on the planarization layer and positioned at an edge of the planarization layer, the first thin film encapsulation layer covers a side surface of the luminous layer, and the second thin film encapsulation layer is disposed on the luminous layer and the first thin film encapsulation layer.

According to the OLED display provided by the embodiment of the present invention, the first thin film encapsulation layer includes a first inorganic layer, an organic layer, and a second inorganic layer sequentially stacked on the planarization layer.

According to the OLED display provided by the embodiment of the present invention, a material of each of the first inorganic layer and the second inorganic layer includes one or more combinations of silicon nitride and silicon oxynitride, and a material of the organic layer is polymethyl methacrylate.

According to the OLED display provided by the embodiment of the present invention, a thickness of the first inorganic layer is 0.2 um, a material of the second inorganic layer is 0.2 um, and a thickness of the organic layer is 1.1 um.

According to the OLED display provided by the embodiment of the present invention, the OLED display device further including a polarizer layer and a cover film, wherein the polarizer layer is disposed on the second thin film encapsulation layer, and the cover film is disposed on the polarizer layer.

According to the OLED display provided by the embodiment of the present invention, a material of the thin film transistor array layer is a low temperature polysilicon.

An embodiment of the present invention provides a method for manufacturing an OLED display panel, including the following steps:

step S10, providing a base substrate, and forming a thin film transistor array layer on the base substrate;

step S20, forming a planarization layer on the thin film transistor array layer;

step S30, forming a first thin film encapsulation layer on the planarization layer;

step S40, etching a pixel hole in a middle portion of the first thin film encapsulation layer, and vapor-depositing a luminous layer in the pixel hole; and

step S50, forming a second thin film encapsulation layer on the luminous layer and the first thin film encapsulation layer.

According to the method for manufacturing the OLED display panel provided by the embodiment of the present invention, the step S30 includes the following steps:

step S301, forming a first inorganic layer on the planarization layer by a plasma enhanced chemical vapor deposition process, and controlling a temperature within a range of 350° C. to 400° C.;

step S302, forming an organic layer on the first inorganic layer by an inkjet printing process; and

step S302, forming a second inorganic layer on the organic layer by a plasma enhanced chemical vapor deposition process, and controlling a temperature within a range of 350° C. to 400° C.

According to the method for manufacturing the OLED display panel provided by the embodiment of the present invention, a material of each of the first inorganic layer and the second inorganic layer includes one or more combinations of silicon nitride and silicon oxynitride, and a material of the organic layer is polymethyl methacrylate.

According to the method for manufacturing the OLED display panel provided by the embodiment of the present invention, the method further including the following steps:

step S60, forming a polarizer layer on the second thin film encapsulation layer; and

step S70, forming a cover film on the polarizer layer.

According to the method for manufacturing the OLED display panel provided by the embodiment of the present invention, a material of the cover film is a glass.

### Beneficial Effect

The beneficial effects of the present invention are as follows. An OLED display panel, a manufacturing method thereof, and an OLED display device are provided by the present invention, which uses a high-temperature thin film encapsulation process to form a first thin film encapsulation layer covering a side of a luminous layer to replace a pixel definition layer structure. This increases side-encapsulation capability of the OLED display panel and improves lateral water-oxygen resistance of a cathode and anode, thereby improving water-oxygen resistance of the OLED display panel as a whole, and further improving service life of the OLED display device. Moreover, high thermal stability of the product and overall foldable performance are improved, and the process is simple and suitable for mass production.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic cross-sectional structure diagram of an organic light-emitting diode (OLED) display panel according to a first embodiment of the present invention.

FIG. 2 is a flowchart of a method for manufacturing an OLED display panel according to a second embodiment of the present invention.

FIGS. 3A-3F are schematic flowcharts of the method for manufacturing the OLED display panel according to the second embodiment of the present invention.

### DETAILED DESCRIPTION OF EMBODIMENTS

The following description of each embodiment, with reference to the accompanying drawings, is used to exemplify specific embodiments which may be carried out in the present invention. Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention. In the drawings, components having similar structures are denoted by the same numerals.

The present invention is directed to an organic light-emitting diode (OLED) display panel, a manufacturing method thereof, and an OLED display device in the conventional art, which have poor lateral water-oxygen resistance of cathodes and anodes due to a low processing temperature in a thin film encapsulation forming process, and easily cause an edge failure in light-emitting devices. These defects can be resolved by the present embodiments.

### First Embodiment

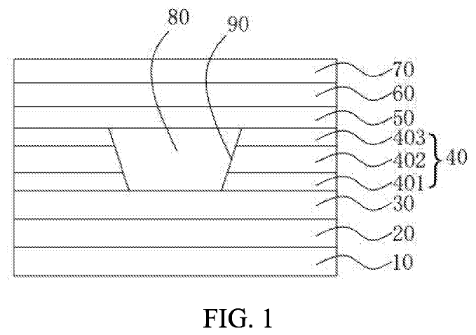

As shown in FIG. 1, an OLED display panel provided by an embodiment of the present invention includes a base substrate 10, a thin film transistor array layer 20, a planarization layer 30, a luminous layer 80, and a thin film encapsulation layer.

Meanwhile, the base substrate 10 is a flexible substrate, and a material thereof can be polyimide film (PI). The thin film transistor array layer 20 is disposed on an upper surface of the base substrate 10, and a material of the thin film transistor array layer 20 can be a low temperature poly-silicon (LTPS). The planarization layer 30 is disposed on an upper surface of the thin film transistor array layer 20. The luminous layer 80 is disposed on an upper surface of the planarization layer 30 and positioned in a middle portion of the planarization layer 30. The luminous layer 80 is disposed in a pixel hole 90. It should be noted that the thin film transistor array layer 20, the planarization layer 30, and the luminous layer 80 are all conventional structures and are not described in details in the present embodiment.

The thin film encapsulation layer includes a first thin film encapsulation layer 40 and a second thin film encapsulation layer 50. The first thin film encapsulation layer 40 is disposed on the upper surface of the planarization layer 30 and positioned at an edge of the planarization layer 30. The first thin film encapsulation layer 40 is disposed on a same layer as the luminous layer 80, and the first thin film encapsulation layer 40 completely covers a side of the luminous layer 80 to prevent an interior of the luminous layer 80 from water-oxygen in the air penetrating through a side of the OLED display panel. The second thin film encapsulation layer 50 is disposed on an upper surface of the luminous layer 80 and an upper surface of the first thin film encapsulation layer 40 to prevent the interior of the luminous layer 80 from the water-oxygen in the air penetrating through a top of the OLED display panel. Thereby, water-oxygen resistance of the OLED display panel is improved, further improving service life of an OLED display device using the OLED display panel in the present embodiment.

The first thin film encapsulation layer 40 includes a first inorganic layer 401, an organic layer 402, and a second inorganic layer 403 which are sequentially stacked on the planarization layer 30. Adopting an alternating stacked inorganic/organic composite film can not only better isolate moisture, but can also effectively reduce pinholes in the first inorganic layer 401 and the second inorganic layer 403 and cracks formed by grain boundary defects. Moreover, because an organic material in the organic layer 402 has high adsorption capacity and low diffusivity, this can make the organic layer 402 laterally transport the water-oxygen slowly, thereby enhancing the encapsulating effect and extending the service life of the luminous layer 80.

Specifically, each of the first inorganic layer 401 and the second inorganic layer 403 can be composed of silicon nitride (SiN) or silicon oxynitride (SiON), and of course, can also be composed of a combination of silicon nitride or silicon oxynitride. The organic layer 402 can be composed of polymethyl methacrylate (PMAA), and of course, can be composed of other organic materials, which is not limited thereto in the present embodiment.

Specifically, a thickness of the first inorganic layer 401 is 0.2 um, a material of the second inorganic layer 403 is 0.2 um, and a thickness of the organic layer 402 is 1.1 um.

Furthermore, a structure of the second thin film encapsulation layer 50 can be similar to that of the first thin film encapsulation layer 40, and the alternating stacked inorganic/organic composite film can also be used, which is not repeated here.

Furthermore, the OLED display panel further includes a polarizer layer (POL) 60 and a cover film 70, wherein the polarizer layer 60 is disposed on an upper surface of the second thin film encapsulation layer. The cover film 70 is disposed on an upper surface of the polarizer layer 60 to protect the OLED display panel from damage. A material of the cover film 70 can be glass.

Compared with the conventional art, the OLED display panel provided in the present embodiment uses the first thin film encapsulation layer 40 to replace a pixel definition layer structure in the conventional art, which improves the high thermal stability of the product and overall foldable performance, and the process is simple and suitable for mass production.

### Second Embodiment

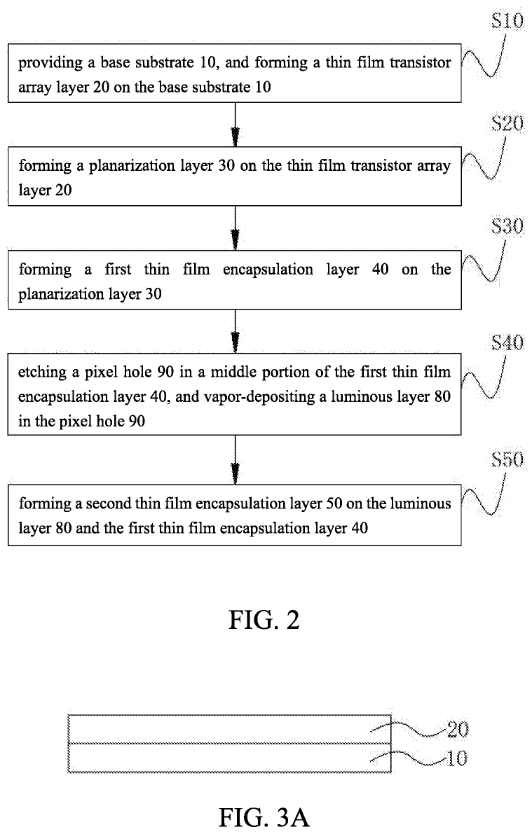

As shown in FIG. 2, a method for manufacturing an OLED display panel according to an embodiment of the present invention includes the following steps.

Step S10, providing a base substrate 10, and forming a thin film transistor array layer 20 on the base substrate 10.

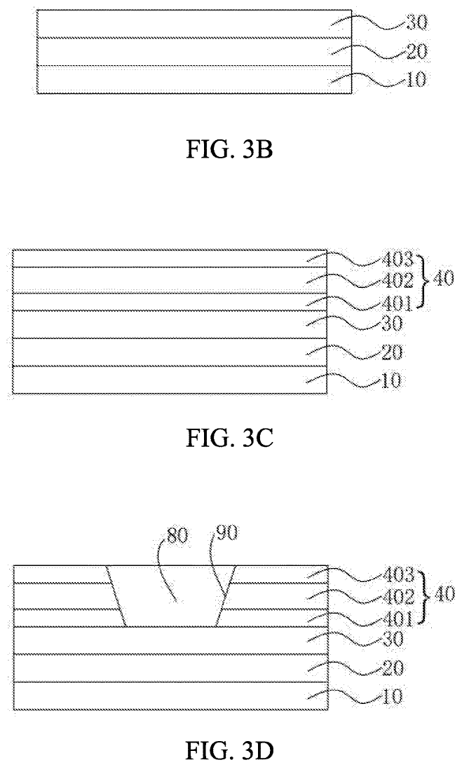

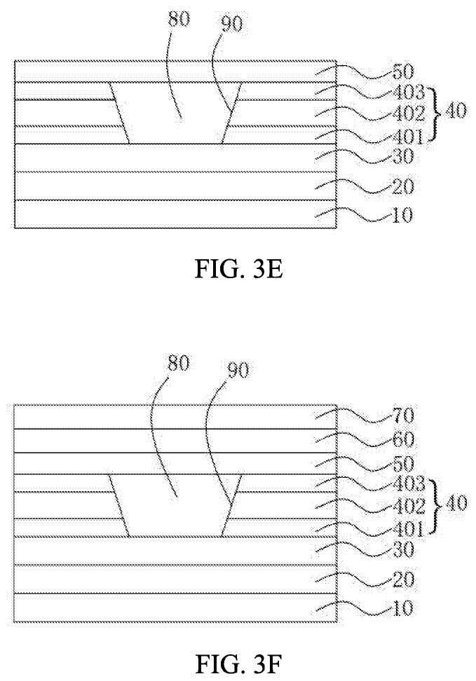

Specifically, as shown in FIG. 3A, the base substrate 10 is a flexible substrate, and the material of the thin film transistor array layer 20 is LTPS.

Step S20, forming a planarization layer 30 on the thin film transistor array layer 20.

Specifically, as shown in FIG. 3B, a material of the planarization layer 30 can be silicon nitride.

Step S30, forming a first thin film encapsulation layer 40 on the planarization layer 30.

Specifically, as shown in FIG. 3C, in order to improve the encapsulating effect of the first thin film encapsulation layer 40, the step S30 can specifically include the following steps:

step S301, forming a first inorganic layer 401 on the planarization layer 30 by a plasma enhanced chemical vapor deposition process, and controlling a temperature within a range of 350° C. to 400° C.,

step S302, forming an organic layer 402 on the first inorganic layer 401 by an inkjet printing process; and

step S302, forming a second inorganic layer 403 on the organic layer 402 by a plasma enhanced chemical vapor deposition process, and controlling a temperature within a range of 350° C. to 400° C.

It can be understood that the first thin film encapsulation layer 40 is composed of the first inorganic layer 401, the organic layer 402, and the second inorganic layer 403 which are sequentially formed. Compared with the conventional art, since the first thin film encapsulation layer 40 is formed by a high temperature process, the manufacturing method of the OLED display panel provided in the present embodiment can make the first inorganic layer 401, the organic layer 402, and the second inorganic layer 403 have better adsorption capacity and lower moisture diffusion ability, thereby effectively increasing the encapsulating effect; meanwhile, the first thin film encapsulation layer 40 has better high thermal stability.

It should be noted that materials of the first inorganic layer 401 and the second inorganic layer 403 include one or more combinations of silicon nitride and silicon oxynitride; and a material of the organic layer 402 is polymethyl methacrylate, of course, materials of the first inorganic layer 401, the second inorganic layer 403, and the organic layer 402 can also be other materials, which is not limited thereto in the present embodiment.

Specifically, a thickness of the first inorganic layer 401 is 0.2 um, a material of the second inorganic layer 403 is 0.2 um, and a thickness of the organic layer 402 is 1.1 um.

Step S40, etching a pixel hole 90 in a middle portion of the first thin film encapsulation layer 40, and vapor-depositing a luminous layer 80 in the pixel hole 90.

Specifically, as shown in FIG. 3D, the pixel hole 90 is formed by etching in the middle portion of the first thin film encapsulation layer 40, and the planarization layer is exposed in the pixel hole 90. A size of the pixel hole 90 is etched according to a size of the pixel definition layer in the conventional art; after that, the luminous layer 80 is formed by vapor-deposition in the pixel hole 90, and the first thin film encapsulation layer 40 covers the side of the luminous layer 80, which replaces the pixel definition layer structure in the conventional art. It can prevent the interior of the luminous layer 80 from the water-oxygen in the air penetrating through the side of the OLED display panel, and enhance the lateral water-oxygen resistance of the overall structure. The phenomenon of edge failure in the luminous layer 80 can be fundamentally solved.

Furthermore, step S50, forming a second thin film encapsulation layer 50 on the luminous layer 80 and the first thin film encapsulation layer 40.

Specifically, as shown in FIG. 3E, the temperature is controlled below 85° C., and a low-temperature thin film encapsulation process is used to form the second thin film encapsulation layer 50 on the luminous layer 80 and the first thin film encapsulation layer 40, which can prevent the interior of the luminous layer 80 from the water-oxygen in the air penetrating through the top of the OLED display panel. The thin film encapsulation layer of the OLED display panel consists by the first thin film encapsulation layer 40 and the second thin film encapsulation layer 50 together, wherein the structure of the second thin film encapsulation layer 50 can be similar to that of the first thin film encapsulation layer 40, and the alternating stacked inorganic/organic composite film can also be used, which is not repeated here.

Since the luminous layer 80 is formed after the first thin film encapsulation layer 40 is formed by a high temperature thin film encapsulation process, and the second thin film encapsulation layer 50 is formed by a low temperature thin film encapsulation process, this prevents a situation in which a processing temperature for making the thin film encapsulation layer cannot have a good compatibility level with the luminous layer 80.

Furthermore, as shown in FIG. 3F, the method for manufacturing the OLED display panel further includes the following steps:

step S60, forming a polarizer layer 60 on the second thin film encapsulation layer 50; and

step S70, forming a cover film 70 on the polarizer layer 60.

Specifically, a material of the cover film 70 can be glass.

### Third Embodiment

An embodiment of the present invention further provides an OLED display device, including the OLED display panel in the first embodiment. The OLED display device can be any product or component having a display function, such as a mobile phone, a tablet computer, a television, and a digital camera. At the same time, the OLED display device has the technical effects of the OLED display panel in the first embodiment, which will not be repeated one by one here.

The beneficial effects of the present invention are as follows. An OLED display panel, a manufacturing method thereof, and an OLED display device are provided by the present invention, which uses a high-temperature thin film encapsulation process to form a first thin film encapsulation layer covering a side of a luminous layer to replace a pixel definition layer structure. This increases side-encapsulation capability of the OLED display panel and improves lateral water-oxygen resistance of a cathode and anode, thereby improving water-oxygen resistance of the OLED display panel as a whole, and further improving service life of the OLED display device. Moreover, high thermal stability of the product and overall foldable performance are improved, and the process is simple and suitable for mass production.

Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

1. An organic light-emitting diode (OLED) display panel, comprising:
a base substrate;
a thin film transistor array layer disposed on the base substrate;
a planarization layer disposed on the thin film transistor array layer;
a luminous layer disposed on the planarization layer and positioned in a middle portion of the planarization layer; and
a thin film encapsulation layer comprising a first thin film encapsulation layer and a second thin film encapsulation layer, wherein the first thin film encapsulation layer is disposed on the planarization layer and positioned at an edge of the planarization layer, the first thin film encapsulation layer covers a side surface of the luminous layer, and the second thin film encapsulation layer is disposed on the luminous layer and the first thin film encapsulation layer.

2. The OLED display panel according to claim 1, wherein the first thin film encapsulation layer comprises a first inorganic layer, an organic layer, and a second inorganic layer sequentially stacked on the planarization layer.

3. The OLED display panel according to claim 2, wherein a material of each of the first inorganic layer and the second inorganic layer comprises one or more combinations of silicon nitride and silicon oxynitride, and a material of the organic layer is polymethyl methacrylate.

4. The OLED display panel according to claim 2, wherein a thickness of the first inorganic layer is 0.2 um, a thickness material of the second inorganic layer is 0.2 um, and a thickness of the organic layer is 1.1 um.

5. The OLED display panel according to claim 1, further comprising a polarizer layer and a cover film, wherein the polarizer layer is disposed on the second thin film encapsulation layer, and the cover film is disposed on the polarizer layer.

6. The OLED display panel according to claim 5, wherein a material of the cover film is a glass.

7. The OLED display panel according to claim 1, wherein a material of the thin film transistor array layer is a low temperature polysilicon.

8. The OLED display panel according to claim 1, wherein the base substrate is a flexible substrate.

9. An organic light-emitting diode (OLED) display device, comprising the OLED display panel of claim 1, the OLED display panel comprising:
the base substrate;
the thin film transistor array layer disposed on the base substrate;
the planarization layer disposed on the thin film transistor array layer;
the luminous layer disposed on the planarization layer and positioned in the middle portion of the planarization layer; and
the thin film encapsulation layer comprising the first thin film encapsulation layer and the second thin film encapsulation layer, wherein the first thin film encapsulation layer is disposed on the planarization layer and positioned at the edge of the planarization layer, the first thin film encapsulation layer covers the side surface of the luminous layer, and the second thin film encapsulation layer is disposed on the luminous layer and the first thin film encapsulation layer.

10. The OLED display device according to claim 9, wherein the first thin film encapsulation layer comprises a first inorganic layer, an organic layer, and a second inorganic layer sequentially stacked on the planarization layer.

11. The OLED display device according to claim 10, wherein a material of each of the first inorganic layer and the second inorganic layer comprises one or more combinations of silicon nitride and silicon oxynitride, and a material of the organic layer is polymethyl methacrylate.

12. The OLED display device according to claim 11, wherein a thickness of the first inorganic layer is 0.2 um, a thickness of the second inorganic layer is 0.2 um, and a thickness of the organic layer is 1.1 um.

13. The OLED display device according to claim 9, further comprising a polarizer layer and a cover film, wherein the polarizer layer is disposed on the second thin film encapsulation layer, and the cover film is disposed on the polarizer layer.

14. The OLED display device according to claim 9, wherein a material of the thin film transistor array layer is a low temperature polysilicon.

15. A method for manufacturing an organic light-emitting diode (OLED) display panel, comprising following steps:
step S10, providing a base substrate, and forming a thin film transistor array layer on the base substrate;
step S20, forming a planarization layer on the thin film transistor array layer;
step S30, forming a first thin film encapsulation layer on the planarization layer;
step S40, etching a pixel hole in a middle portion of the first thin film encapsulation layer, and vapor-depositing a luminous layer in the pixel hole; and
step S50, forming a second thin film encapsulation layer on the luminous layer and the first thin film encapsulation layer.

16. The method for manufacturing the OLED display panel according to claim 15, wherein the step S30 comprises following steps:
step S301, forming a first inorganic layer on the planarization layer by a plasma enhanced chemical vapor deposition process, and controlling a temperature within a range of 350° C. to 400° C.;
step S302, forming an organic layer on the first inorganic layer by an inkjet printing process; and
step S302, forming a second inorganic layer on the organic layer by the plasma enhanced chemical vapor deposition process, and controlling the temperature within the range of 350° C. to 400° C.

17. The method for manufacturing the OLED display panel according to claim 16, wherein a material of each of the first inorganic layer and the second inorganic layer comprises one or more combinations of silicon nitride and silicon oxynitride, and a material of the organic layer is polymethyl methacrylate.

18. The method for manufacturing the OLED display panel according to claim 15, further comprising following steps:
step S60, forming a polarizer layer on the second thin film encapsulation layer; and
step S70, forming a cover film on the polarizer layer.

19. The method for manufacturing the OLED display panel according to claim 18, wherein a material of the cover film is a glass.
